(19) United States
(12) Patent Application Publication
(10) Pub. No.: US 2020/0274477 A1
(43) Pub. Date: Aug. 27, 2020

(54) FAULT DETERMINATION APPARATUS, MOTOR DRIVING SYSTEM, AND FAILURE DETERMINATION METHOD

(71) Applicant: RENESAS ELECTRONICS CORPORATION, Tokyo (JP)

(72) Inventor: Makoto NAKAMURA, Tokyo (JP)

(21) Appl. No.: 16/783,583

(22) Filed: Feb. 6, 2020

(30) Foreign Application Priority Data
Feb. 22, 2019 (JP) 2019-030432

(51) Int. Cl. H02P 29/024; G01R 31/34; H02P 29/40; G06N 20/00; G06N 99/00; H02P 27/06; H02H 7/122

(52) U.S. Cl. CPC H02P 29/024; G01R 31/34; H02P 29/40; H02H 7/122; G06N 99/00; H02P 27/06; G06N 20/00

(57) ABSTRACT

Fault diagnosis is easily performed using the detected value of the motor and the learned model thereof. The device 50 has a sampling unit 51 for sampling the current at the time of regeneration of the motor, a determination unit 52 for determining the failure of the motor using data obtained from the sampling result by the sampling unit 51, and learned models learned in advance using data obtained from the sampling result of the current at the time of regeneration of the motor when the state of soundness of the motor is a predetermined state.

### CROSS-REFERENCE TO RELATED APPLICATIONS

The disclosure of Japanese Patent Application No. 2019-030432 filed on Feb. 22, 2019 including the specification, drawings and abstract is incorporated herein by reference in its entirety.

### BACKGROUND

The present disclosure relates to a failure determination device, a motor drive system, and a failure determination method.

In recent years, various techniques using machine learning have been proposed. There are disclosed techniques listed below.

[Patent Document 1] Japanese Unexamined Patent Application Publication No. 2017-127099.

[Non-Patent Document 1] Vittaya Tipsuwanporn, et al.,“Fault Detection In compressor Using FFT Algorithm”, Proceedings of the World Congress on Engineering and Computer Science 2013 Vol I, WCECS 2013, 23-25 Oct., 2013, San Francisco, USA.

For example, Patent Document 1 discloses a machine learning device capable of adjusting values of a resistor regeneration start voltage and a resistance regeneration stop voltage which are optimal for respective motors.

As for detection of motor failure, for example, Non-Patent Document 1 is known. This document provides a theoretical expression of the frequency component which appears in the event of a motor failure.

### SUMMARY

The inventors have discovered that the following problems arise if the learning data of the motor in the force action state is used when the determination of the failure of the motor or the part related to the motor is performed using machine learning. In an environment in which the motor is powered, there are many parameters that affect the sensed value of the motor, e.g., the current supplied to the motor, so that various frequency components appear for the sensed value. This makes the design of the machine learning model difficult. Alternatively, even if a machine learning model can be designed, a great deal of learning data must be collected for machine learning of the model.

On the other hand, none of the above-mentioned methods examines the determination of a failure using machine learning. Therefore, there is a need for a technique that can easily perform fault diagnosis using the detected value of the motor and the learned model thereof. In the following disclosure, “failure” includes a preliminary stage of failure.

Other objects and novel features will become apparent from the description of this specification and the accompanying drawings.

According to one embodiment, the failure determination device comprises a sampling unit for sampling the current at the time of regeneration of the motor, and a determination unit for determining the fault of the motor using the data obtained from the sampling results and the learned models.

According to the above-mentioned embodiment, it is possible to easily perform the fault diagnosis using the detected value of the motor and the learned model thereof.

### BRIEF DESCRIPTION OF THE DRAWINGS

FIG. 1 is a schematic diagram showing an example of a configuration of a motor driving system according to an embodiment.

FIG. 2 is a block diagram showing an exemplary configuration of a failure determination device according to an outline of an embodiment.

FIG. 3 is a block diagram showing an example of the configuration of an MCU.

FIG. 4 is a graph for explaining the frequency control and current control by the control unit.

FIG. 5 is a graph showing an example of the relationship between the turning speed and time of the motor during regeneration.

FIG. 6 is an example of a flowchart showing the flow of operations for the failure diagnosis.

FIG. 7A is a schematic perspective view of a mechanism having two gears that rotate by rotation of a motor.

FIG. 7B is a side view of the gear shown in 7A.

FIG. 8 is an example of a flowchart showing the flow of diagnostic operations including multiple diagnostic methods.

FIG. 9 is a graph showing an example of an analysis result by FFT when the motor is driving.

FIG. 10 is an example of a flowchart showing the flow of operations for the failure diagnosis.

FIG. 11 is a schematic diagram showing an example of a configuration of a motor driving system.

FIG. 12 is a schematic diagram showing an exemplary configuration of a motor drive system provided as a device different from a control system device in which a diagnostic device performs a process for diagnosing a failure controls an inverter.

### DETAILED DESCRIPTION

For clarity of explanation, the following description and drawings are appropriately omitted and simplified. In addition, the elements described in the drawings as functional blocks for performing various processes can be configured as a CPU (Central Processing Unit), a memory, and other circuits in terms of hardware, and are realized by a program loaded into a memory in terms of software. Therefore, it is understood by those skilled in the art that these functional blocks can be realized in various forms by hardware alone, software alone, or a combination thereof, and the present invention is not limited to any of them. In the drawings, the same elements are denoted by the same reference numerals, and a repetitive description thereof is omitted as necessary.

Also, the program described above may be stored and provided to a computer using various types of non-transitory computer readable media. Non-transitory computer readable media includes various types of tangible storage media. Examples of non-transitory computer-readable media include magnetic recording media (e.g., a flexible disk, a magnetic tape, a hard disk drive), magneto-optical recording media (e.g., a magneto-optical disk), CD-ROM (Read Only Memory, a CD-R, a CD-R/W, a solid-state memory (e.g., masked ROM, PROM(Programmable ROM), EPROM (Erasable PROM, flash ROM, RAM (Random Access Memory)). The program may also be supplied to the computer by various types of transitory computer-readable media. Examples of transitory computer-readable media include an electrical signal, an optical signal, and an electromagnetic wave. The transitory computer readable medium may provide the program to the computer via a wired or a wireless communication path, such as an electrical wire and an optical fiber.

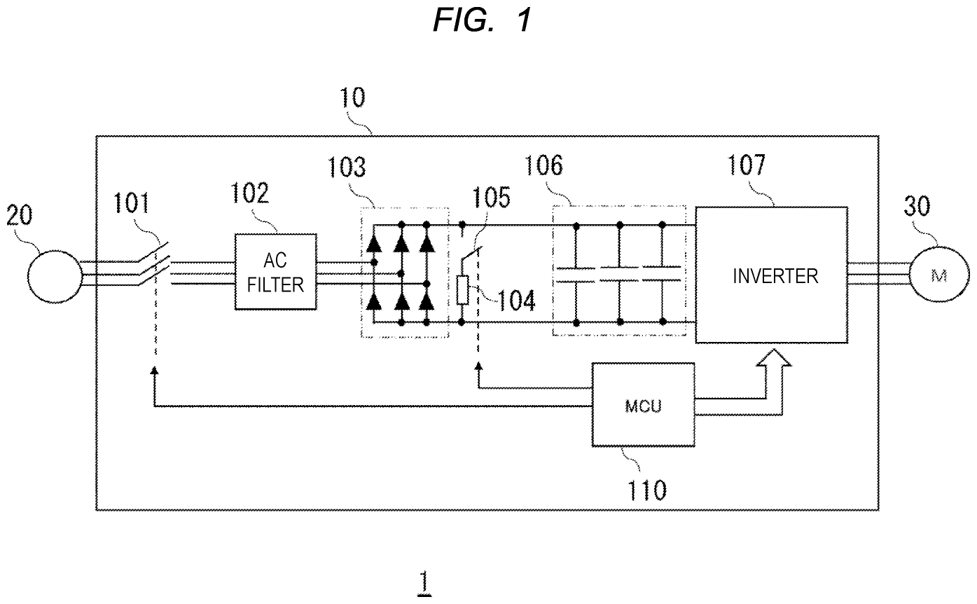

FIG. 1 is a schematic diagram showing an example of a configuration of a motor driving system according to an embodiment. The motor drive system 1 includes a three phase power supply 20, a motor drive device 10, and a motor 30. The three-phase power supply 20 supplies a three-phase alternating current transmitted from a power station or the like to the motor drive device 10. The motor 30 is a three phase motor and is controlled by the motor drive device 10. The motor drive device 10 is a device for controlling the motor 30. The motor drive device 10 includes a power supply switch 101, an AC filter 102, a rectifier 103, a resistor 104, a resistor switch 105, an electrolytic capacitor 106, inverter 107, and a MCU (Micro Control Unit) 110.

The power supply switch 101 is a switch for turning on and off a three phase current from the three phase power supply 20, and operates by switch switching signals from the MCU110. The AC filter 102 is provided to prevent noises from the inverter 107 from propagating to the outside of the motor drive device 10, and includes an AC reactor. The AC filter 102 is provided between the power supply switch 101 and the rectifier 103. The rectifier 103 is a converter for converting an alternating current from the three-phase power supply 20 into a direct current. The resistor 104 is a circuit element that consumes power supplied from the motor 30 when the motor 30 is in a regeneration state. The resistor switch 105 is a switch for turning on/off the connection of the resistor 104 to the DC circuit, and operates in response to switch switching signals from the MCU110. The MCU110 controls the on-time and the off-time of the resistor switch 105, thereby controlling the power consumed by the resistor 104 when the motor 30 is regenerated.

The electrolytic capacitor 106 has a plurality of smoothing capacitors connected to the inverter 107. More specifically, the electrolytic capacitor 106 is provided between the rectifier 103 and the inverter 107. When the motor 30 is powered, the inverter 107 supplies a three phase AC current (alternating current) to the motor 30 in accordance with the PWM (pulse width modulation) signals from the MCU110. The inverter 107 converts the three phase AC current from the motor 30 into a direct current during regeneration of the motor 30. The MCU110 includes a processor such as a CPU, a memory, a peripheral circuit, and the like, and controls the entire motor drive device 10.

Here, in the motor drive system 1 described above, when the determination of the failure of the motor 30 or the part related to the motor 30 is performed by using machine learning, it is considered that learning data of the motor in the force action operation state is used. In this case, variations in various values affect the detected values of the motor, such as the current value and the voltage value. The various values referred to herein include, for example, the voltage value of the three phase power supply 20, the voltage difference between the phases of the three phase power supply 20, the internal impedance of the AC filter 102, and the inductance value of the AC filter 102. Therefore, even if it becomes difficult to design the machine learning model using the detected value, or even if the design of the machine learning model is possible, a very large amount of learning data must be collected in consideration of the above-mentioned variation.

On the other hand, when the motor 30 is regenerated, the supply of power from the three phase power supply 20 can be cut off, and the operation of the AC filter 102 is not necessary. That is, it is unnecessary to take the above-described variation into consideration with respect to the detection value at the time of regeneration of the motor 30. Therefore, the model can be constructed with less learning data as compared with the machine learning using the detected value at the time of power running of the motor 30.

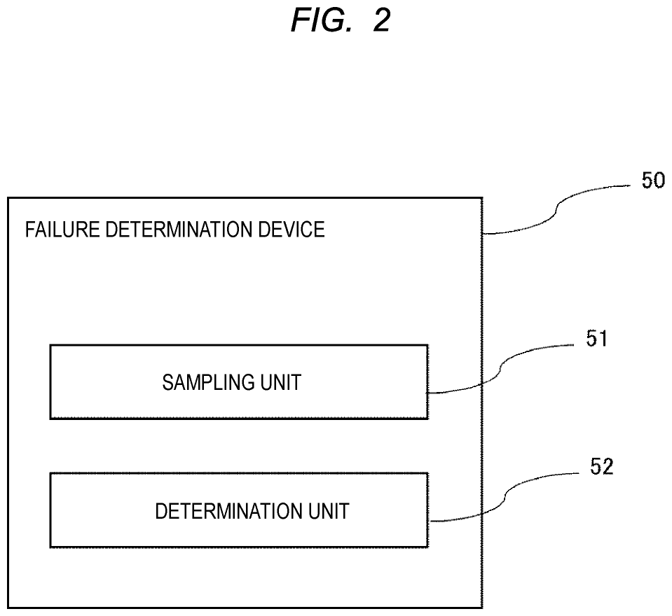

Therefore, the failure determination device according to the outline of the embodiment has the following device. FIG. 2 is a block diagram showing an exemplary configuration of a failure determination device according to an outline of an embodiment. As shown in FIG. 2, the failure determination device 50 includes a sampling unit 51 and a determination unit 52. The failure determination device 50 is implemented as, for example, the above-described MCU110, but may be implemented as another device.

The sampling unit 51 samples the current at the time of regeneration of the motor 30. The determination unit 52 determines the failure of the motor 30 using the data obtained from the sampling result by the sampling unit 51 and the learned model. The learned model is a model learned in advance by using data obtained from a sampling result of a current at the time of regeneration of the motor 30 in the case where the state of soundness of the motor 30 is a predetermined state. It should be noted that the state of soundness is a predetermined state, for example, a state in which the motor 30 is normal, but a state in which the motor 30 has failed may be used.

According to the failure determination device 50, since the current at the time of regeneration of the motor 30 is sampled as the detected values for the determination using the learned models, the above described variation does not need to be considered. Therefore, the failure determination device 50 can diagnose a failure using a model that can be easily constructed, as compared with a model constructed by machine learning using detected values at the time of power running of the motor 30. In other words, according to the failure determination device 50, it is possible to easily diagnose a fault using the detected values of the motor 30 and the learned models thereof.

Details of the embodiment will be described below.

### Embodiment 1

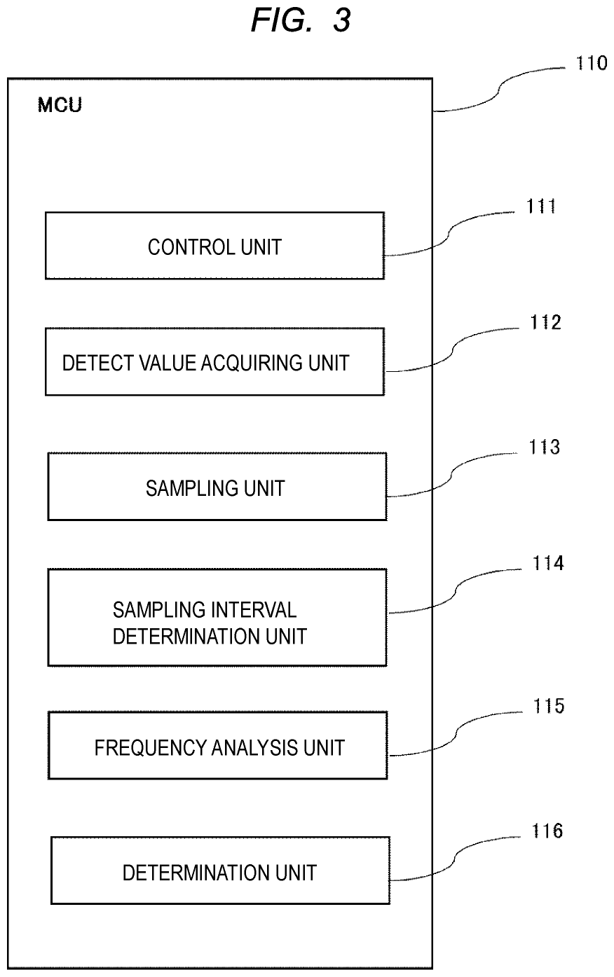

FIG. 3 is a block diagram showing an example of the configuration of an MCU. As shown in FIG. 3, the MCU110 includes a control unit 111, a detect value acquiring unit 112, a sampling unit 113, a sampling interval determination unit 114, a frequency analysis unit 115, and a determination unit 116.

The control unit 111 controls the operation of the motor drive device 10. The control unit 111 is implemented by, for example, a MCU110 processor reading a software (a computer program) from a memory and executing the software, but the control unit 111 may also be implemented as a hardware circuit. The control unit 111 controls the operations of the power switch 101 and the resistor switch 105 by, for example, a switch switching signal. In addition, the control unit 111 performs control to switch the motor 30 between the power running state and the regeneration state. Further, the control unit 111 outputs a PWM signal to the inverter 107, thereby controlling rotation of the motor 30.

In particular, in the present embodiment, the control unit 111 performs the following two types of control in order to make the condition at the time of diagnosing a failure constant.

The first control is a control for changing the rotation speed of the motor 30 at the time of switching the motor 30 from the power running state to the regeneration state to a predetermined rotation speed. In this control, the control unit 111 performs the frequency control by the PWM, thereby setting the rotation speed of the motor 30 at the start of the regeneration operation, that is, the rotation speed of the motor 30 at the end of the power running operation, to a predetermined rotation speed. Hereinafter, this control is sometimes referred to as frequency control.

The second control is a control in which the electric power consumed when the motor 30 is regenerated becomes a predetermined value. In this control, the control unit 111 controls the opening and closing of the resistor switch 105 so that the electric power consumed by the resistor 104 becomes a predetermined value when the motor 30 is in regeneration operation. That is, the control unit 111 controls the current flowing through the resistor 104 at the time of regeneration. Hereinafter, this control is sometimes referred to as current control.

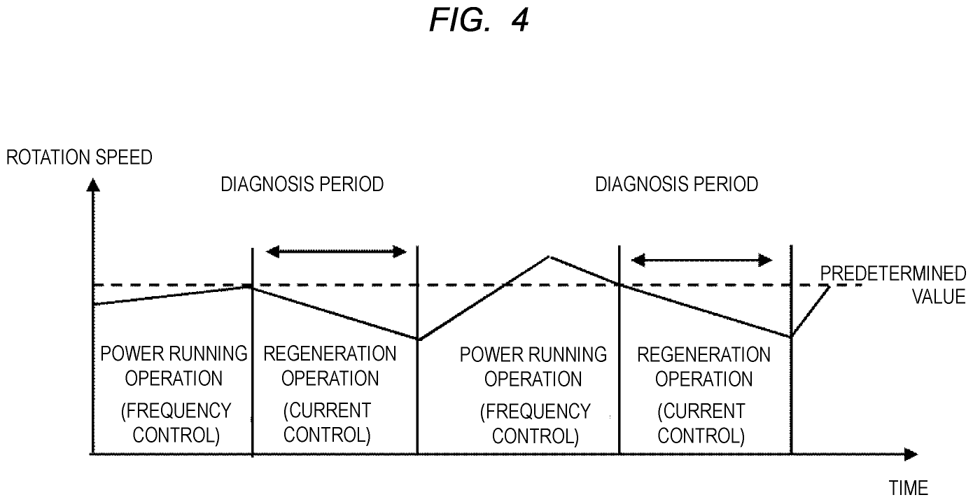

FIG. 4 is a graph for explaining the frequency control and current control by the control unit. In the graph shown in FIG. 4, the horizontal axis represents time, and the vertical axis represents the rotation speed of the motor 30. As shown in FIG. 4, the frequency control is performed while the motor 30 is in the power running state, and the rotation speed of the motor 30 is set to a predetermined value. Then, when the rotation speed of the motor 30 reaches a predetermined value, the control unit 111 switches the operation state of the motor 30 to the regeneration operation. That is, the control unit 111 sets the rotation speed at the start of the regeneration operation to a predetermined value by the frequency control. During the regeneration operation, the control unit 111 performs current control and controls the consumed power to a predetermined value. Then, the failure diagnosis is performed during the regeneration operation. Therefore, the above described control by the control unit 111 makes it possible to make constant the conditions for the rotation speed and the power consumption when the fault diagnosis is performed. In other words, the diagnostic conditions can always be the same. As a result, it is possible to perform failure determination with high accuracy using the learned model learned using data only at the time of regeneration. In the present embodiment, the control unit 111 executes both frequency control and current control, but may execute only one of them. It is preferable that the control unit 111 performs these controls, but these controls do not necessarily have to be performed.

The detect value acquiring unit 112 is an interface circuit for acquiring a detected value (measured value) of an electrical value of the motor 30 during regeneration operation. Specifically, the detect value acquiring unit 112 acquires analog data of the current value output from the motor 30 during the regeneration operation. The detect value acquiring unit 112 may acquire analog data of the voltage value of the current output from the motor 30 during the regeneration operation, or may acquire analog data of the voltage value of the electrolytic capacitor 106. Generally, in order to perform PWM control, the inverter 107 is provided with an element for detecting a current, for example, a shunt resistor. Such an element may also be used in obtaining a current value for fault determination. That is, the current at the time of regeneration of the motor 30 may be detected using a shunt resistor provided for controlling the inverter 107. In this manner, failure diagnosis can be realized without adding a new element for detecting a current.

The sampling unit 113 is an analog-to-digital converter that samples the analog data of the detection value acquired by the detect value acquiring unit 112 at the sampling interval determined by the sampling interval determination unit 114, and outputs the digital data. The sampling interval determination unit 114 determines the sampling interval based on the frequency of the current acquired by the detect value acquiring unit 112, that is, the frequency of the current of the motor 30 at the time of regeneration. The sampling interval determination unit 114 is implemented, for example, by a MCU110 processor reading and executing software (computer program) from the memory, but may be implemented as a hardware circuit.

The frequency analysis unit 115 performs frequency analysis on the sampling result by the sampling unit 113. That is, the frequency analysis unit 115 performs frequency analysis on the digital data output from the sampling unit 113. In present embodiment, the frequency analysis unit 115 performs FFT analysis. Frequency analysis unit 115 is implemented, for example, by a MCU110 processor reading and executing software (computer program) from the memory, but may be implemented as a hardware circuit.

The determination unit 116 determines the failure of the motor 30 using the data (that is, the analysis result by the frequency analysis unit 115) obtained from the sampling result by the sampling unit 113 and the learned model learned in advance. The determination unit 116 is implemented by, for example, a MCU110 processor reading software (computer programs) from a memory and executing the software (computer programs), but may be implemented as hardware circuits. Here, the learned model is learned in advance using data (that is, the analysis result by the frequency analysis unit 115) obtained from the sampling result of the current at the time of regeneration of the motor when the state of the soundness of the motor 30 is a predetermined state. For example, the model is a neural network, but other machine learning models may be used.

The learned model may be a model learned in advance using the following data. The data used for the learning may be data obtained from the sampling result of the current at the time of regeneration of the motor 30 when the state of the soundness of the motor 30 and the parts connected to the motor 30 is a predetermined state. Specifically, the data obtained from the sampling result is an analysis result by the frequency analysis unit 115. In this case, the determination unit 116 determines a failure of the motor 30 and a part connected to the motor 30. The part connected to the motor 30 is, for example, part directly or indirectly connected to the rotation axis of the motor 30, and specifically include, but is not limited to, a bearing, a gear, a fan belt, and the like. According to such a configuration, it is possible to include the part related to the motor as the object of the determination of the failure.

Here, a method of determining the sampling interval in the present embodiment will be described. During regeneration of the motor 30, the energy stored is determined by the inertial force and the rotational speed of the motor 30. Therefore, the rotation speed of the motor 30 differs between immediately after the start of regeneration and after a predetermined period of time has elapsed. In other words, the rotational speed of the motor 30 gradually decreases during regeneration. Here, the rotation speed corresponds to the frequency of the electric current of the motor 30. Therefore, an appropriate sampling interval in the case of acquiring a predetermined number (M) or more of the sampling data of the current over n cycles of the current waveform of the motor 30 depends on the rotation speed. Therefore, in present embodiment, the sampling interval is determined as follows.

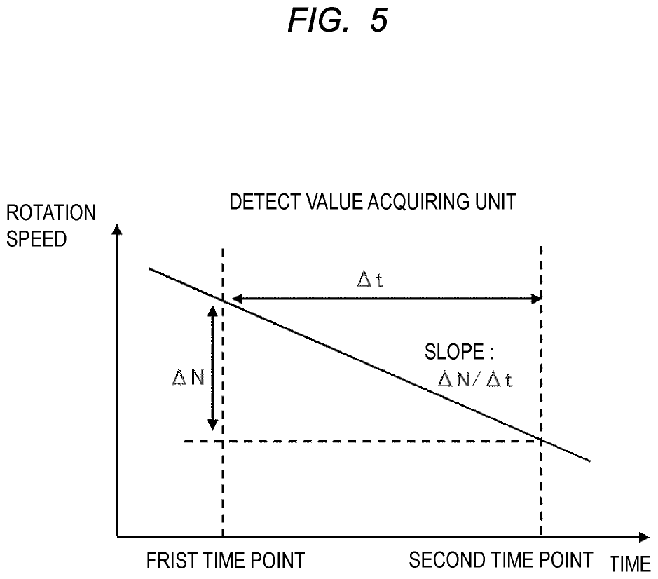

FIG. 5 is a graph showing an example of the relationship between the turning speed and time of the motor during regeneration. Although FIG. 5 shows a graph in which the rotation speed drops linearly, the rotation speed does not always drop linearly in practice. In present embodiment, for example, the change in velocity is predicted as follows. The sampling interval determination unit 114 measures the rotation speed of the motor 30 at the first time point and the rotation speed of the motor 30 at the second time point while the regeneration operation is continuing. Here, the second time point is a speed at a time point when a predetermined time Δt has elapsed from the first time point. The predetermined time Δt may be a mask time, which will be described later, or may be a time longer or shorter than the mask time. The difference between the rotation speed at the first time point and the rotation speed at the second time point is defined as ΔN. As a result, the slope α (=ΔN/Δt), which is an estimated value of the rate of change of the rotation speed during the regeneration operation, can be calculated. The sampling interval determination unit 114 calculates the rate of change α of the rotation speed in advance before performing the failure diagnosis. That is, in the regeneration operation performed at any time before the regeneration operation in which the failure diagnosis is performed, the sampling interval determination unit 114 determines the sampling interval in the regeneration operation in which the failure diagnosis is performed.

The relationship between the rotational speed of the motor and the current of the motor is expressed by the following equation (1).

N=120/P×fₑ (1)

In equation (1), N is the rotational speed of the motor, fₑ is the synchronous frequency (i.e., the frequency of the current), and P is the number of poles of the motor 30. Therefore, the sampling interval determining unit 114 can calculate the rotational velocity based on the frequency fₑ acquire by measuring the period of the current obtained by the detected value acquiring unit 112.

The sampling interval determining unit 114 determines the sampling interval by using the previously calculated rate of change α of the rotation speed at the start of the regeneration operation in which the failure diagnosis is performed. In present embodiment, the determination unit 116 diagnoses a failure by using the sampled data after a predetermined masking time has elapsed since the regeneration operation started. Therefore, the sampling interval determination unit 114 determines a sampling interval corresponding to the rotation speed after a predetermined mask time has elapsed from the start of the regeneration operation. The reason why the masking time is provided is that there is an influence of the transient characteristic immediately after the regeneration operation. By not using the sampling data from the start of the regeneration operation to the elapse of the predetermined mask time for the fault diagnosis, it is possible to eliminate the influence of the transient characteristic immediately after the regeneration operation.

Assuming that the rotation speed at the time of starting the regeneration operation is Ni and the mask time is Tₑₛₜ, the estimated value Nₑₛₜ of the rotation speed after the mask time has elapsed is expressed by the following equation (2).

Nₑₛₜ=N₁−α×Tₑₛₜ (2)

As described above, since there is the relationship of Equation (1) between the rotation speed of the motor and the current of the motor, Equation (2) can be expressed as the following Equation (3).

Nₑₛₜ=120/P×f₁−α×Tₑₛₜ (3)

where the f₁ is the current frequency (synchronized frequency) at the start of regeneration operation where the failure diagnosis is performed.

The estimated value fₑₛₜ of the current frequency after the masking time elapses can be calculated by the following equation (4) from the above (1).

fₑₛₜ=Nₑₛₜ/120/P (4)

That is, by estimating the rotational speed Nₑₛₜ after the mask time has elapsed based on the relational expression of Expression (3), the frequency fₑₛₜ of the current after the mask time has elapsed can be estimated based on the relational expression of Expression (4).

If the frequency fₑₛₜ can be estimated, the sampling interval Tₛₐₘₚ can be determined by the following equation (5). In Equation (5), n is the number of cycles of current that needs to be sampled for failure diagnosis. M is the number of sampling data necessary for the fault diagnosis. That is, M is the number of samples required to realize a predetermined resolution in the FFT analysis.

Tₛₐₘₚ=n/fₑₛₜ/M (5)

The sampling interval determining unit 114 calculates the sampling interval Tₛₐₘₚ and sets it in the sampling unit 113. The sampling unit 113 acquires M or more sampling data at Tₛₐₘₚ time intervals.

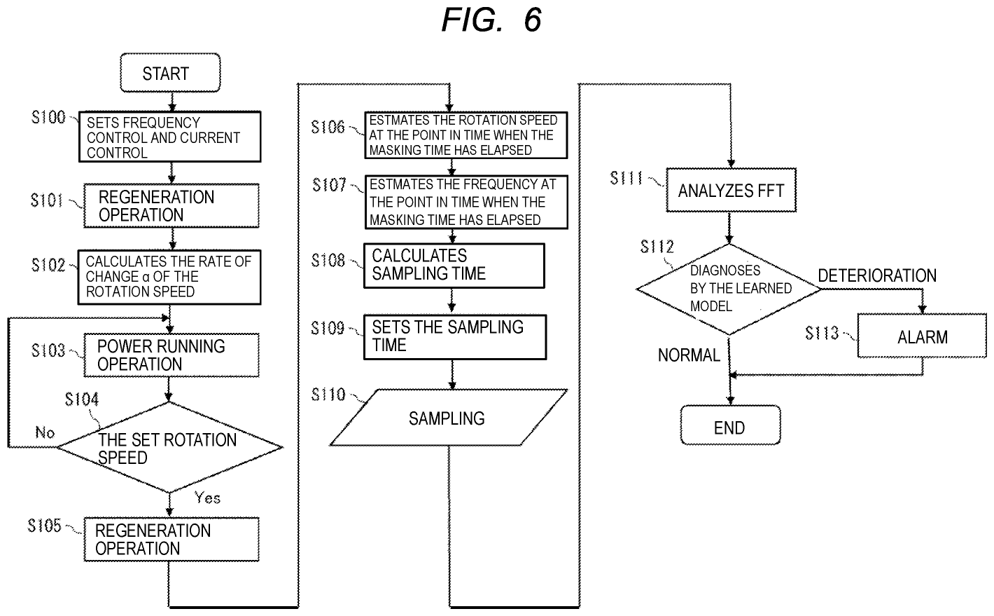

FIG. 6 is an example of a flowchart showing the flow of operations for the failure diagnosis. Referring to FIG. 6, the flow of the operation of the fault diagnosis will be described below.

In step S100, the control unit 111 sets a target rotational speed for performing frequency control and a power consumed by the resistor 104 when performing current control.

Next, in step S101, the control unit 111 switches the motor 30 to the regeneration operation in order to calculate the rate of change α of the rotational speed during the regeneration operation. Prior to switching from the power running operation to the regeneration operation in step S101, the control unit 111 may perform frequency control such that the regeneration operation starts at the rotational speed set in step S100. In step S101, the control unit 111 may perform current control such that the power set in step S100 is consumed.

Next, in step S102, the sampling interval determining unit 114 measures the rotation speed of the motor 30 at the first time point and the rotation speed of the motor 30 at the second time point while the regeneration operation is continuing. Then, the sampling interval determining unit 114 calculates the rate of change α of the rotation speed during the regeneration operation.

Next, in step S103, the control unit 111 switches the motor 30 to the power running operation. Then, the control unit 111 performs frequency control so that the rotational speed becomes the rotational speed set in the step S100. Until the rotation speed of the motor 30 reaches the rotation speed set in step S100, the control unit 111 continues the power running operation (NO in step S104). When the rotation speed of the motor 30 reaches the rotation speed set in step S100 (Yes in step S104), the process proceeds to step S105.

In step S105, the control unit 111 switches the motor 30 to the regeneration operation in order to diagnose a failure. Then, the control unit 111 performs current control so that the power set in the step S100 is consumed. Thereafter, the control unit 111 continues the regeneration operation of the motor 30 accompanied by the current control.

In step S106, the sampling interval determination unit 114 measures the synchronization frequency f₁ at the start of the regeneration operation, and calculates an estimated value Nₑₛₜ of the rotational speed at the point in time when the masking time has elapsed from the start of the regeneration operation based on equation (3). At this time, the value calculated in step S102 is used as the rate of change α, and a predetermined time is used as the masking time Tₑₛₜ.

In step S107, the sampling interval determining unit 114 calculates the estimated value fₑₛₜ of the frequency of the current after the masking period has elapsed, using the estimated value Nₑₛₜ of the rotational velocity calculated in step S106 and equation (4).

In step S108, the sampling interval determination unit 114 calculates the sampling interval Tₛₐₘₚ by using the estimated frequency fₑₛₜ calculated in step S107 and the equation (5), and determines the sampling interval used by the sampling unit 113. In this case, a predetermined value is used as the value of the number of periods n and the value of the number of sampling data M. As described above, the sampling interval is determined. In this manner, the sampling interval determination unit 114 estimates the frequency of the current of the motor 30 after a predetermined time has elapsed from the start of regeneration of the motor 30, and determines the sampling interval based on the estimated frequency. For this reason, it is possible to set an appropriate sampling interval while eliminating the influence of the transient characteristic immediately after the regeneration is started. That is, it is possible to suppress the consumption of resources due to excessive sampling while suppressing the deterioration of the failure determination accuracy. Since the rate of change of the number of revolutions at the time of regeneration differs depending on the difference in the motor inertia force, setting of the sampling interval is necessary for each system set.

Here, the above mentioned value of the number of periods n will be supplemented with the description. When a failure diagnosis of a motor-related component that rotates in accordance with the rotation of the rotation shaft of the motor 30 is performed, it is necessary to perform sampling on a motor current waveform corresponding to at least one rotation of the component. This will be explained with reference to the figures.

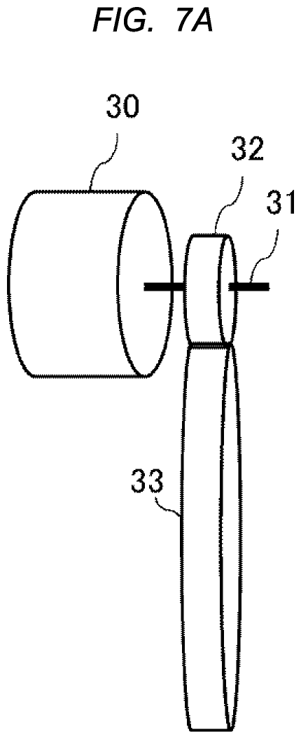

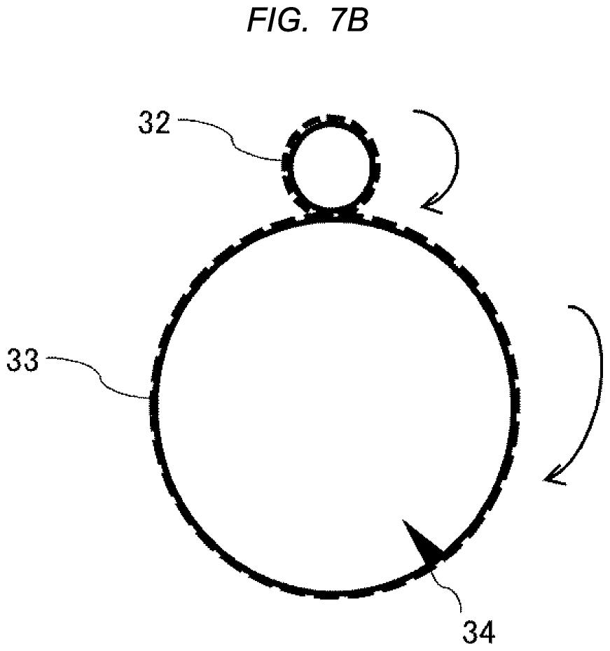

FIG. 7A is a schematic perspective view of a mechanism having two gears that rotate by rotation of a motor.

Also, FIG. 7B is a side view of the gear shown in 7A. In the mechanism shown in the drawing 7A, the gear 32 is rotated by the rotation of the rotation shaft 31 of the motor 30, and the gear 33 differing in the number of teeth from the gear 32 is rotated in accordance with the rotation of the gear 32. That is, the gear 33 is a motor related part that is indirectly connected to the motor 30. Here, when diagnosing the gear 33, it is impossible to detect the tooth breakage 34 or the like of the gear 33 unless sampling of the motor current waveform is performed in a period covering one rotation of the gear 33. For this reason, it is necessary to set in advance a period in which at least one rotation of the gear 33 can be covered with respect to the number of frequency n. As described above, in order to diagnose the failure of various part directly or indirectly connected to the motor 30, it is necessary to sample the motor current waveform in a period covering at least one rotation of the part.

The description will return to the flowchart. In step S109, the sampling interval determination unit 114 sets the sampling unit 113 to perform sampling at the sampling interval determined in step S108.

Next, in step S110, the sampling unit 113 samples the regenerative current of the motor 30. In particular, the sampling unit 113 samples the regenerative current after the masking time has elapsed from the start of the regeneration operation at sampling intervals determined by the step S108.

Next, in step S111, the frequency analysis unit 115 performs FFT analysis on the sampling result obtained by the sampling unit 113. In particular, the frequency analysis unit 115 performs FFT analysis on the sampling data after the mask time has elapsed from the start of the regeneration operation.

Next, in step S112, the determination unit 116 inputs the analysis result obtained in step S111 to the learned models, and performs failure determination. If the output result of the learned model indicates that the motor 30 or its related part is normal (“normal” in step S112), the diagnostic process is terminated. Otherwise (“degradation” in step S112), the determination unit 116 outputs an alarm (step S113).

In present embodiment, failure diagnoses are performed using detected values during regeneration operation. Therefore, the following effects can also be obtained. That is, while the influence of switching noise or the like occurs during the power running operation, such an influence can be eliminated during the regeneration operation. That is, when the motor is regenerated, the switching of the power element of the inverter 107 is stopped, and the switching noise peculiar to the operation of the inverter 107 is not generated. Therefore, at the time of regeneration, the S/N ratio in the detection value can be improved as compared with at the time of power running, which contributes to improvement of the determination accuracy.

During the power running operation, the voltage of the electrolytic capacitor 106 contains a frequency component due to an external factor. The external factors include, for example, imbalance of power supply voltages in respective phases, and variation in impedances of the AC filter 102. Therefore, the frequency component of the motor current may be affected. That is, it is necessary to consider the influence of the voltage of the electrolytic capacitor 106 when the frequency analysis of the motor current is performed. For this reason, it is difficult to separate the deterioration of the electrolytic capacitor 106 and the failure of the motor 30 for analysis. In contrast, in the diagnosis at the time of regeneration operation, the influence of the voltage of the electrolytic capacitor can be eliminated.

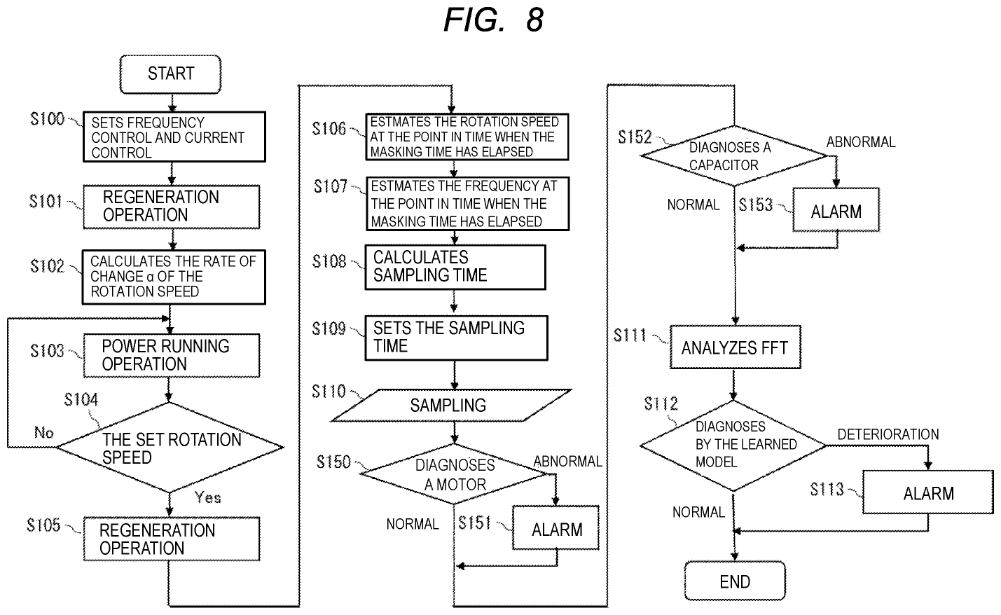

Incidentally, if the motor is a normal motor, the voltage of each phase of the motor at the time of regeneration is output in equilibrium. Therefore, it is also possible to detect an abnormality of the motor 30 by checking the degree of imbalance of the voltage of the motor 30 at the time of regeneration, instead of diagnosis using the result of frequency analysis of the current and the learned model. Energy is stored in the electrolytic capacitor 106 at the time of regeneration, and the electrolytic capacitor 106 can be diagnosed by measuring the time constant at that time. A diagnostic flow combining these diagnoses is shown in FIG. 8. FIG. 8 is an example of a flowchart showing the flow of diagnostic operations including multiple diagnostic methods. The flowchart shown in FIG. 8 differs from the flowchart shown in FIG. 6 in that step S153 is added from step S150 between step S110 and step S111. Differences from the flowchart shown in FIG. 6 will be described below.

In the flow chart shown in FIG. 8, in step S110, the sampling unit 113 performs sampling of the voltage of the electrolytic capacitor 106 in addition to the current from the motor 30. Note that a predetermined condition is used as the sampling condition of the voltage of the electrolytic capacitor 106.

In step S150, the determination unit 116 determines the failure of the motor 30 based on whether or not the voltages of the three phase AC currents at the time of regeneration of the motor 30 are balanced. Therefore, the determination unit 116 checks the degree of imbalance of the voltage of the motor 30 at the time of regeneration. If the motor is normal, the output voltages of the phases of the motor at the time of regeneration should be in equilibrium. Therefore, it is possible to detect the abnormality of the motor 30 by detecting the unbalance of the output voltages of the respective phases. Specifically, the determination unit 116 confirms the equilibrium state of the output voltage of each phase based on the phase current (regenerative current). When the output voltage of each phase is in equilibrium, the total value of the phase currents is zero. Therefore, the determination unit 116 calculates a total value of the phase currents obtained as the sampling data, and determines whether the motor 30 is normal or not based on the calculated value. When the determination unit 116 determines that the motor 30 is normal (“normal” in step S150), the process proceeds to step S152. Otherwise (“abnormal” in step S150), the determination unit 116 outputs an alarm (step S151). After step S151, the process proceeds to step S152.

In step S152, the determining unit 116 determines degradation of the electrolytic capacitor 106 based on the voltage of the electrolytic capacitor 106 during regeneration of the motor 30. As a result, the electrolytic capacitor 106 can also be diagnosed. The internal resistance of the electrolytic capacitor 106 increases with deterioration. Therefore, the degree of deterioration of the electrolytic capacitor 106 can be determined by measuring the time constant when the motor voltage at the time of regeneration is charged in the electrolytic capacitor 106. Therefore, the determination unit 116 measures the time constant based on the voltage of the electrolytic capacitor 106 obtained as sampling data, for example, and determines the deterioration of the electrolytic capacitor 106 based on whether or not the time constant exceeds a predetermined threshold value. When the determination unit 116 determines that the electrolytic capacitor 106 is normal (“normal” in step S152), the process proceeds to step S111. Otherwise (“abnormal” in step S150), the determination unit 116 outputs an alarm (step S153). After step S153, the process proceeds to step S111. According to the diagnosis according to the flowchart shown in FIG. 8, after the motor 30 and the electrolytic capacitor 106 are diagnosed, the diagnosis can be performed by the learned model.

### Embodiment 2

Next, a description will be given of a second embodiment. Hereinafter, descriptions of configurations and operations that overlap with those of the first embodiment will be omitted as appropriate. When all of the data obtained by the frequency analysis is input to a machine learning model such as a neural network, a large amount of data causes a decrease in the calculation speed and an increase in the memory consumption. Here, the theoretical equation of the frequency component f_{fault} appearing at the time of motor failure is expressed as the following equation (6) (see Non-Patent Document 1).

$$\begin{matrix}[ Equation 1 ] & \\ {f}_{fault} = {f}_{e} \pm k \frac{{f}_{e}}{p / 2} & ( 6 )\end{matrix}$$

In equation (6), fₑ is the synchronous frequency, i.e., the frequency of the fundamental. Also, p is the number of poles. k is an arbitrary integer of 1 or more. That is, k=1, 2, 3, . . . As shown in Equation (6), the frequency component that appears at the time of motor failure is a sideband wave. That is, the result of the frequency analysis on the sideband wave is data contributing to the failure diagnosis. Therefore, in present embodiment, data contributing to diagnosing a failure is extracted from data obtained by frequency analysis.

For this reason, in the present embodiment, the frequency analysis unit 115 analyzes frequency components of a predetermined frequency band contributing to the determination of the failure, and the determination unit 116 inputs the analysis result into the learned models and performs the determination process. Therefore, the frequency analysis unit 115 performs preprocessing (filtering process) using a notched filter or the like before performing FFT processing, and removes signal components that do not contribute to fault diagnostics.

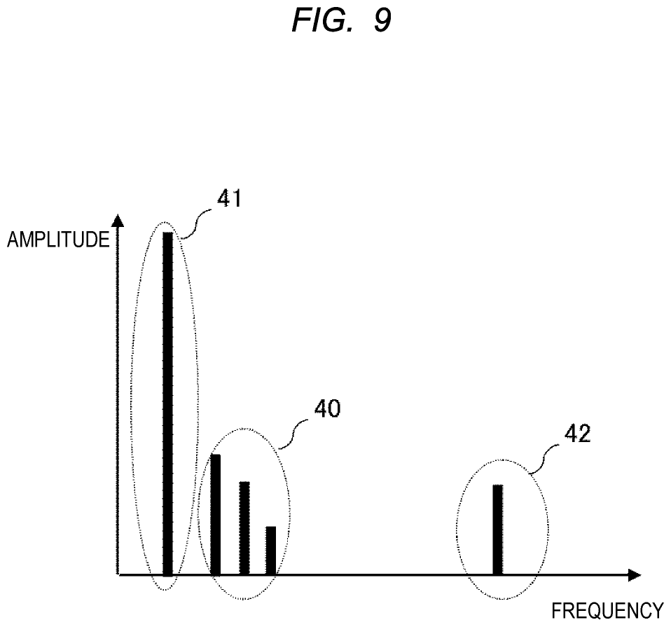

FIG. 9 is a graph showing an example of an analysis result by FFT when the motor is driving. In the graph of FIG. 9, the horizontal axis represents frequency, and the vertical axis represents amplitude (spectrum intensity). As shown in FIG. 9, the analysis result by the FFT includes not only the amplitude value of the data group 40 contributing to the failure diagnosis but also the amplitude value of the fundamental wave 41, the amplitude value of the high frequency wave 42 generated by the influence of switching, and the like. In present embodiment, on the other hand, since FFT analysis is performed on the detected values during regeneration operation, the amplitude of the high frequency 42 can be excluded. The amplitude of the fundamental wave 41 can be excluded by performing the filtering process. In the present embodiment, only the amplitudes of the data group 40 contributing to the failure diagnosis are used to perform the diagnosis by machine learning. As shown in FIG. 9, the amplitude value of the data group 40 contributing to the failure diagnosis is smaller than that of the fundamental wave 41. In the case of the motor failure diagnosis, it is necessary to detect a small difference between the amplitude in the normal state and the amplitude in the abnormal state, and therefore it is necessary to sufficiently secure the resolution. According to the present embodiment, the amplitude of the fundamental waves 41 can be removed, so that enough resolution can be ensured.

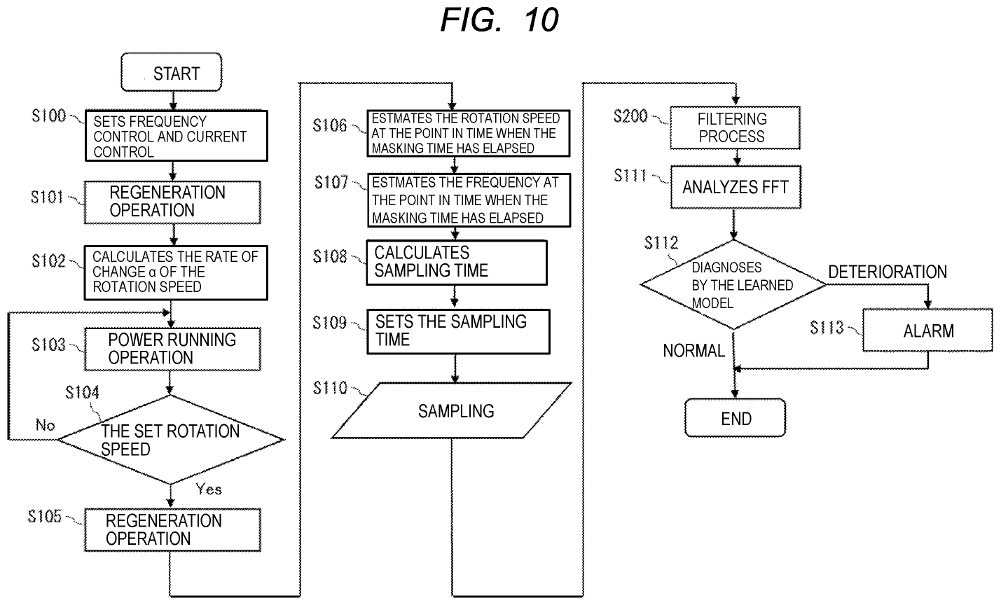

FIG. 10 is an example of a flowchart showing the flow of operations for the failure diagnosis. The flowchart shown in FIG. 10 differs from the flowchart shown in FIG. 6 in that a filtering process (step S200) is added prior to the step S111. In step S200, the filtering process described above is performed. In the flow chart shown in FIG. 8, step S200 may be added prior to step S111.

Second embodiment has been described above. According to the present embodiment, since the filtering process is performed, the diagnosis can be performed by machine learning using only data contributing to the failure diagnosis. Therefore, it is possible to reduce the data input to the model, and it is possible to suppress a decrease in the calculation speed and an increase in the memory consumption. In addition, it is possible to sufficiently secure the resolution necessary for diagnosis.

### Embodiment 3

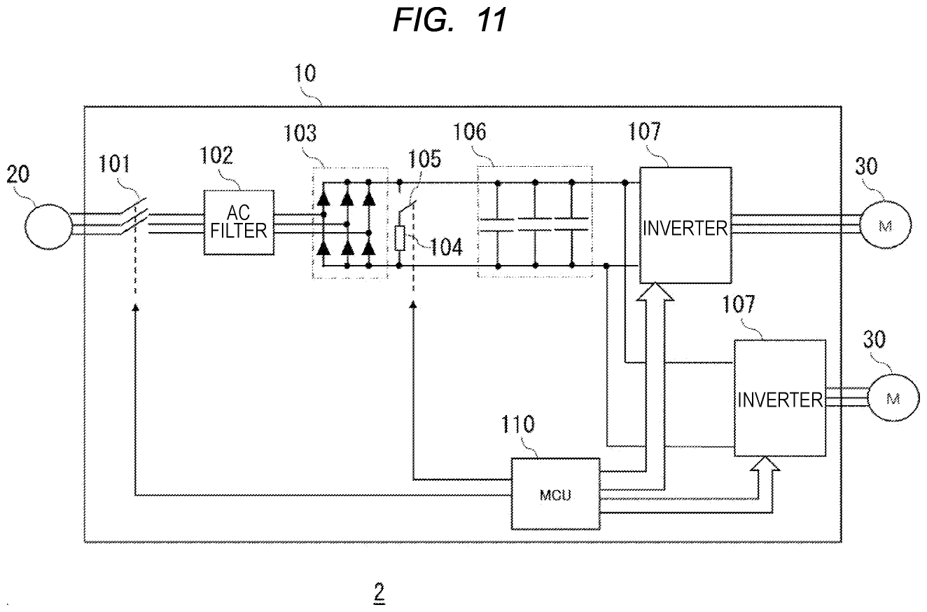

FIG. 11 is a schematic diagram showing an example of a configuration of a motor driving system. As shown in FIG. 11, the motor drive system 2 is different from the above described embodiment in that a motor and a plurality of inverters for driving the motor are provided. Specifically, the motor drive system 2 differs from the motor drive system 1 shown in FIG. 1 in that a pair of motors 30 and inverters 107 are added. In present embodiment, the MCU110 controls both inverters 107.

When the failure diagnosis is performed during regeneration operation of the motor, the power running operation of the motor is not possible during the failure diagnosis. Therefore, the system operated by driving the motor is stopped during this period. In present embodiment, the motor drive system 2 includes a plurality of motors and a plurality of inverters corresponding to the motors. Therefore, the control unit 111 of the MCU110 can perform the power running operation of the other motors while regenerating and diagnosing a failure of any motor. In other words, according to the motor drive system 2 of the present embodiment, it is possible to suppress complete stoppage of the system operated by driving the motor. Further, the control unit 111 of the MCU110 may control other motors to be powered by using regenerative energy from the motor during regeneration operation. Since the power supply switch can be turned off while such control is being performed, it is possible to diagnose the failure of other motors during regeneration operation while the motors are being powered without being affected by external factors. The external factor is, for example, imbalance of power supply voltages in respective phases, or variation of impedances of the AC filter 102. Incidentally, not only the current control by the resistor 104 but also the current control by consuming power by the power running operation of the motor may be performed at the time of regeneration.

As a system that operates by driving a motor, an arbitrary system can be targeted. For example, the system operated by driving the motor may be a hydraulic system, an elevator system, or an electric vehicle system.

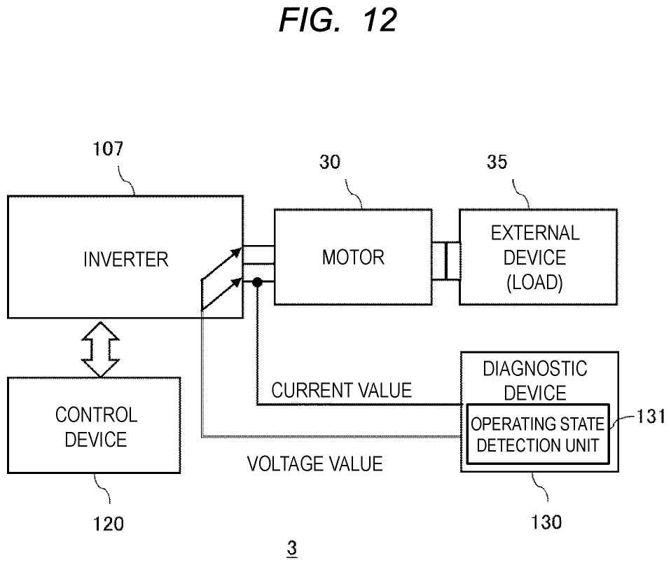

In the above described embodiments, the control device (MCU) for controlling the inverter performs the treatment for the failure diagnosis, but the device for performing the processing for the fault diagnosis and the device for controlling the inverter may be a separate device. FIG. 12 is a schematic diagram showing an exemplary configuration of the motor drive system 3 provided as a separate device from the control device 120 in which a diagnostic device (fault determination device) 130 for performing a process for fault diagnosis controls the inverter 107.

FIG. 12 is a schematic diagram showing an exemplary configuration of a motor drive system provided as a device different from a control system device in which a diagnostic device performs a process for diagnosing a failure controls an inverter.

As shown in FIG. 12, the motor drive system 3 includes a motor 30, an external device 35, inverter 107 for driving the motor 30, a control device 120, and a diagnostic device 130. The external device 35 is a device which is operated by driving of the motor 30. That is, the external device 35 is a load of the motor 30. The control device 120 is a device for controlling the inverter 107. The device 130 is a device for performing failure diagnosis of the motor 30. Here, the control device 120 has an inverter control function among the functions of the MCU110 described above, and the diagnostic device 130 has a failure diagnosis function among the functions of the MCU110 described above. Specifically, for example, the control device 120 is a device including the control unit 111 described above. Further, for example, the diagnostic device 130 is a device including the above described detect value acquiring unit 112, sampling interval determination unit 114, sampling unit 113, frequency analysis unit 115, and determination unit 116.

If device, which performs the process for fault diagnosis, and device, which controls the inverter, are separate, the diagnosis device 130 cannot directly control the inverter 107. Therefore, the diagnostic device 130 needs a function of judging the operating state of the motor 30, that is, a function of judging whether the motor 30 is in the power running state or the regeneration state. For this purpose, for example, the diagnostic device 130 further includes an operating state detection unit 131 for detecting the operating state of the motor 30 by acquiring the voltage value and the current value of the motor 30.

The operating state detection unit 131 detects the regeneration state and the power running state of the motor 30 based on the voltage value and the current value of the motor 30. The operating state detection unit 131 calculates the product (i.e., the power value) of the voltage value and the current value for each phase of the three phase AC current between the motor 30 and the inverter 107. Then, the operating state detection unit 131, when the sum of the product of the voltage value and the current value is positive, the motor 30 is determined to be a power running state, if the sum is negative, it is determined to be a regeneration state.

If it is determined that the motor 30 is in a regeneration state, the device 130 performs the above-described diagnostic process. According to such a configuration, the above-described diagnosis can be performed even if the device for performing the process for the failure diagnosis and the device for controlling the inverters are different.

Although the invention made by the inventor has been specifically described based on the embodiment, the present invention is not limited to the embodiment already described, and it is needless to say that various modifications can be made without departing from the gist thereof.

What is claimed is:

1. A failure determination device comprising:
a sampling unit for sampling a current at the time of regeneration of a motor; and
a determination unit for determining a failure of the motor using data obtained from a sampling result by the sampling unit and a learned model which has been learned in advance using data obtained from a sampling result of a current at the time of regeneration of the motor when a state of soundness of the motor is a predetermined state.

2. The failure determination device according to claim 1,
wherein the learned model is a model learned in advance using data obtained from a result of sampling current at the time of regeneration of the motor when states of soundness of the motor and of a part connected to the motor are a predetermined state, and
wherein the determination unit determines a failure of the motor and the part.

3. The failure determination device according to claim 1, further comprising,
a sampling interval determination unit for determining a sampling interval based on the frequency of the current, and
wherein the sampling unit performs a sampling operation at the sampling interval determined by the sampling interval determination unit.

4. The failure determination device according to claim 3,
wherein the sampling interval determination unit estimates the frequency of the current after a predetermined time has elapsed from the start of regeneration of the motor, and determines the sampling interval based on the estimated frequency.

5. The failure determination device according to claim 1, further comprising,
a control unit for controlling to change the rotation speed of the motor at the time of switching the motor from the power running state to the regeneration state to a predetermined rotation speed.

6. The failure determination device according to claim 3,
wherein the control unit further controls the electric power consumed during regeneration of the motor to be a predetermined value.

7. The failure determination device according to claim 1, further comprising,
a frequency analysis unit for performing frequency analysis on the sampling result,
wherein the frequency analysis unit performs analysis on frequency components of a predetermined frequency band contributing to determination of failure; and
wherein the determination unit uses the analysis result by the frequency analysis unit as data obtained from the sampling result by the sampling unit.

8. The failure determination device according to claim 1, further comprising,
a regeneration state detection unit for detecting a regeneration state of the motor by acquiring a voltage value and a current value of the motor.

9. A motor drive system comprising:
an inverter for supplying an alternating current to a motor;
a smoothing capacitor coupled to the inverter; and
a failure determination device,
wherein the failure determination device includes
a sampling unit for sampling a current at the time of regeneration of the motor; and
a determination unit for determining a failure of the motor using data obtained from a sampling result by the sampling unit and learned models learned in advance using data obtained from a sampling result of a current at the time of regeneration of the motor when the state of soundness of the motor is a predetermined state.

10. The motor driving system according to claim 9,
wherein the determination unit further determines degradation of a electrolytic capacitor based on a voltage of the electrolytic capacitor at the time of regeneration of the motor.

11. The motor driving system according to claim 9,
wherein the determination unit further determines a failure of the motor based on whether or not the voltages of the three phase alternating currents at the time of regeneration of the motor are balanced.

12. The motor drive system of claim 9, further comprising,
a plurality of motors, wherein the inverter is provided for each of the motors.

13. The motor drive system of claim 9,
wherein a current at the time of regeneration of the motor is detected using a shunt resistor provided for controlling the inverter.

14. A failure determination method comprising:
sampling a current at the time of regeneration of a motor; and
determining a failure of a motor by using data obtained from the sampling result and by using a learned model learned in advance using data obtained from the sampling result of the current at the time of regeneration of the motor when the state of soundness of the motor is a predetermined state.
